(19) United States
(12) Patent Application Publication
(10) Pub. No.: US 2020/0185307 A1
(43) Pub. Date: Jun. 11, 2020

(54) SEMICONDUCTOR STRUCTURE AND METHOD FOR MANUFACTURING THE SAME

(71) Applicant: NANYA TECHNOLOGY CORPORATION, New Taipei City (TW)

(72) Inventor: Hung-Chi TSAI, New Taipei City (TW)

(21) Appl. No.: 16/250,676

(22) Filed: Jan. 17, 2019

Related U.S. Application Data
(60) Provisional application No. 62/776,174, filed on Dec. 6, 2018.

(51) Int. Cl. H01L 23/48; H01L 21/768; H01L 23/522; H01L 23/532; H01L 23/00; H01L 25/07

(52) U.S. Cl. CPC H01L 23/481; H01L 21/76898; H01L 21/76897; H01L 25/074; H01L 23/53295; H01L 24/89; H01L 23/5226

(57) ABSTRACT

The present disclosure relates to a semiconductor structure and a method for manufacturing the same. The semiconductor structure includes a first semiconductor layer, a second semiconductor layer, and a first, a second and a third bonding conductors. The first semiconductor layer includes a first top surface. The second semiconductor layer is disposed over the first semiconductor layer, and the second semiconductor layer includes a second top surface. The first bonding conductor is disposed over the first top surface. The second bonding conductor is disposed over the second top surface. The third bonding conductor is in contact with the first bonding conductor and the second bonding conductor, the first bonding conductor is different from the second bonding conductor, and the third bonding conductor includes a silicide material formed from the first bonding conductor and the second bonding conductor.

### PRIORITY CLAIM AND CROSS-REFERENCE

This application claims the priority benefit of U.S. provisional application Ser. No. 62/776,174, filed on Dec. 6, 2018. The entirety of the above-mentioned patent application is hereby incorporated by reference herein and made a part of this specification.

### TECHNICAL FIELD

The present disclosure relates to a semiconductor structure and a method for manufacturing the same, and more particularly, to a semiconductor structure having a stacking structure and a method for manufacturing the same.

### DISCUSSION OF THE BACKGROUND

Semiconductor devices are essential for many modem applications. With the advancement of electronic technology, semiconductor devices are steadily becoming smaller while incorporating improved integration density of various electronic components, such as transistors, diodes, resistors, capacitors and so on. Due to the miniaturized scale of semiconductor devices, stacked semiconductor structures are widely used, for example, package-on-package (POP) structures, system-in-package (SiP) structures, and the like.

The semiconductor structure may include a first semiconductor layer and a second semiconductor layer bonded to each other through two metal conductors.

However, some problems are incurred with the above-mentioned configuration. For example, metal contact resistance may be insufficient, or power consumption may increase.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a method for manufacturing a semiconductor structure. The method comprises forming a first bonding conductor over a first top surface of a first semiconductor layer, wherein the first bonding conductor is coupled to a first electronic circuit structure formed in the first semiconductor layer; forming a second bonding conductor over a second top surface of a second semiconductor layer, wherein the second bonding conductor is coupled to a second electronic circuit structure formed in the second semiconductor layer; and bonding the first bonding conductor and the second bonding conductor, wherein a third bonding conductor is formed between the first bonding conductor and the second bonding conductor, and the third bonding conductor is in contact with the first bonding conductor and the second bonding conductor, wherein the first bonding conductor is different from the second bonding conductor, and the third bonding conductor includes a silicide material formed from the first bonding conductor and the second bonding conductor.

In some embodiments, a first through semiconductor via (TSV) is formed in the first semiconductor layer, wherein the first TSV is coupled to the first bonding conductor.

In some embodiments, a second TSV is formed in the second semiconductor layer, wherein the second TSV is coupled to the second bonding conductor.

In some embodiments, a portion of the first semiconductor layer is removed from a first bottom surface of the first semiconductor layer, wherein the first TSV is exposed.

In some embodiments, the first electronic circuit structure includes a first electronic component and a first interconnection circuit coupled to the first electronic component, and the second electronic circuit structure includes a second electronic component and a second interconnection circuit coupled to the second electronic component.

In some embodiments, the first electronic component is a first transistor formed on a first substrate of the first semiconductor layer, and the second electronic component includes a second transistor formed on a second substrate of the second semiconductor layer.

In some embodiments, a first TSV in contact with the first interconnection circuit is formed, wherein the first TSV extends from the first interconnection circuit toward a first bottom surface of the first semiconductor layer.

In some embodiments, a first conductive pad and a first conductive plug of the first interconnection circuit are formed, wherein the first TSV extends from the first conductive pad toward the first bottom surface, and the first conductive plug is in contact with the first electronic component and the first conductive pad.

In some embodiments, one of the first bonding conductor and the second bonding conductor includes a silicon material, another of the first and second bonding conductors includes a metal material, and the third bonding conductor is formed through a thermal treating process or an electrical treating process.

In some embodiments, a first dielectric material is formed over the first top surface, wherein the first bonding conductor is embedded in the first dielectric material; and a second dielectric material is formed over the second top surface, wherein the second bonding is conductor is embedded in the second dielectric material.

Another aspect of the present disclosure provides a semiconductor structure. The semiconductor structure comprises a first semiconductor layer including a first top surface and a first electronic circuit structure; a second semiconductor layer disposed over the first semiconductor layer, wherein the second semiconductor layer includes a second top surface and a second electronic circuit structure; a first bonding conductor disposed over the first top surface, wherein the first bonding conductor is coupled to the first electronic circuit structure; a second bonding conductor disposed over the second top surface, wherein the second bonding conductor is coupled to the second electronic circuit structure; and a third bonding conductor disposed between the first bonding conductor and the second bonding conductor, wherein the third bonding conductor is in contact with the first bonding conductor and the second bonding conductor, and wherein the first bonding conductor is different from the second bonding conductor, and the third bonding conductor includes a silicide material.

In some embodiments, a first TSV is disposed in the first semiconductor layer, wherein the first TSV is in contact with the first electronic circuit structure, and the first TSV extends from the first electronic circuit structure toward a first bottom surface of the first semiconductor layer.

In some embodiments, a second TSV is disposed in the second semiconductor layer, wherein the second TSV is in contact with the second electronic circuit structure, and the second TSV extends from the second electronic circuit structure toward a second bottom surface of the second semiconductor layer.

In some embodiments, one of the first bonding conductor and the second bonding conductor includes a silicon material, and another of the first and second bonding conductors includes a metal material.

In some embodiments, the first electronic circuit structure includes a first electronic component and a first interconnection circuit coupled to the first electronic component, and the second electronic circuit structure includes a second electronic component and a second interconnection circuit coupled to the second electronic component.

In some embodiments, the first electronic component is a first transistor formed on a first substrate of the first semiconductor layer, and the second electronic component includes a second transistor formed on a second substrate of the second semiconductor layer.

In some embodiments, a first TSV is in contact with the first interconnection circuit, wherein the first TSV extends from the first interconnection circuit toward a first bottom surface of the first semiconductor layer.

In some embodiments, the first interconnection circuit includes a first conductive pad and a first conductive plug in contact with the first conductive pad, wherein the first TSV extends from the first conductive pad toward the first bottom surface, and the first conductive plug is in contact with the first electronic component.

In some embodiments, the first interconnection circuit includes a second conductive pad and a second conductive plug in contact with the second conductive pad, wherein the second conductive plug is in contact with the second electronic component.

In some embodiments, a first dielectric material is disposed over the first top surface, wherein the first bonding conductor is is embedded in the first dielectric material, and a second dielectric material is disposed over the second top surface, wherein the second bonding conductor is embedded in the second dielectric material.

With the design of the semiconductor structure of the present disclosure, the bonding conductor may include at least a silicide material. This design can effectively decrease the contact resistance between two semiconductor layers and thus consume less power. In addition, the silicide material has better thermal stability.

The foregoing has outlined rather broadly the features and technical advantages of the present disclosure in order that the detailed description of the disclosure that follows may be better understood.

Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims. The disclosure should also be understood to be coupled to the figures' reference numbers, which refer to similar elements throughout the description.

FIG. 1 is a flow diagram illustrating a method for manufacturing a semiconductor structure in accordance with some embodiments of the present disclosure; and

FIGS. 2 to 4 are schematic cross-sectional views illustrating stages of manufacturing a semiconductor structure by the method of FIG. 1 in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

References to “one embodiment,” “some embodiments,” “an embodiment,” “exemplary embodiment,” “other embodiments,” “another embodiment,” etc. indicate that the embodiment(s) of the disclosure so described may include a particular feature, structure, or characteristic, but not every embodiment necessarily includes the particular feature, structure, or characteristic. Further, repeated use of the phrase “in the embodiment” does not necessarily refer to the same is embodiment, although it may.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another element, component, region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

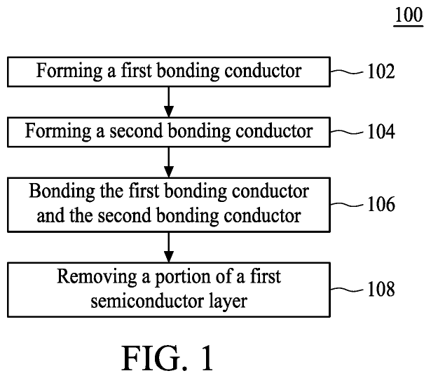

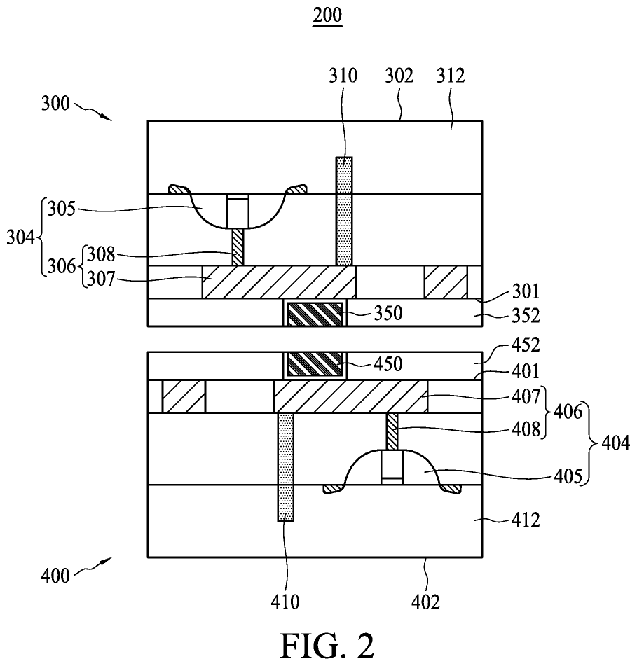

FIG. 1 is a flow diagram illustrating a method 100 for manufacturing a semiconductor structure 200 in accordance with some embodiments of the present disclosure. FIGS. 2 to 4 are schematic cross-sectional views of stages of manufacturing a semiconductor structure in accordance with some embodiments of the present disclosure. In some embodiments, the method 100 includes a number is of operations (102, 104, 106 and 108), and the description and illustration below are not deemed as a limitation as the sequence of the operations.

As shown in FIG. 2, a first semiconductor layer 300 and a second semiconductor layer 400 are provided. The first semiconductor layer 300 has a first top surface 301 and a first bottom surface 302. The second semiconductor layer 400 has a second top surface 401 and a second bottom surface 402.

In operation 102, as shown in FIG. 2, a first bonding conductor 350 is formed over the first top surface 301. The first bonding conductor 350 is coupled to a first electronic circuit structure 304 formed in the first semiconductor layer 300. In some embodiments, the first bonding conductor 350 may be surrounded by a diffusion barrier layer.

In some embodiments, a first dielectric material 352 is formed over the first top surface 301. The first bonding conductor 350 is embedded in the first dielectric material 352. In some embodiments, the first dielectric material 352 is oxide, such as silicon oxide or the like.

In some embodiments, a first through semiconductor via (TSV) 310 is formed in the first semiconductor layer 300. The first TSV 310 is coupled to the first bonding conductor 350. In some embodiments, the first TSV 310 includes a via filled with a conductive material and a diffusion barrier layer surrounding the conductive material.

In some embodiments, the first electronic circuit structure 304 includes a first electronic component 305 and a first interconnection circuit 306 coupled to the first electronic component 305. In some is embodiments, the first electronic component 305 is a first transistor formed on a first substrate 312 of the first semiconductor layer 300. In some embodiments, the first electronic component 305 may be another component, such as a diode, a resistor, or the like.

In some embodiments, the first TSV 310 is in contact with the first interconnection circuit 306. The first TSV 310 extends from the first interconnection circuit 306 toward the first bottom surface 302. In some embodiments, the first interconnection circuit 306 includes a first conductive pad 307 and a first conductive plug 308 formed in the first semiconductor layer 300.

In some embodiments, the first TSV 310 extends from the first conductive pad 307 toward the first bottom surface 302. The first conductive plug 308 is in contact with the first electronic component 305 and the first conductive pad 307. In some embodiments, the first TSV 310 may be formed by performing an etching process, then a deposition process, and so on.

In operation 104, a second bonding conductor 450 is formed over the second top surface 401 of the second semiconductor layer 400 as shown in FIG. 2. The second bonding conductor 450 is coupled to a second electronic circuit structure 404 formed in the second semiconductor layer 400.

In some embodiments, a second dielectric material 452 is formed over the second top surface 401. The second bonding conductor 450 is embedded in the second dielectric material 452. In some embodiments, the second dielectric material 452 is silicon oxide or other suitable oxide.

In some embodiments, the second electronic circuit structure is 404 includes a second electronic component 405 and a second interconnection circuit 406 coupled to the second electronic component 405. In some embodiments, a second TSV 410 is formed in the second semiconductor layer 400. The second TSV 410 is coupled to the second bonding conductor 450. In some embodiments, the second TSV 410 extends from the second interconnection circuit 406 toward the second bottom surface 402.

In some embodiments, the second electronic component 405 includes a second transistor formed on a second substrate 412 of the second semiconductor layer 400. In some embodiments, the second electronic component 405 may include a resistor, a diode, a capacitor, or the like.

In some embodiments, the second interconnection circuit 406 includes a second conductive pad 407 and a second conductive plug 408 in contact with the second conductive pad 407. The second conductive plug 408 is in contact with the second electronic component 405. In some embodiments, the second conductive pad 407 and the second conductive plug 408 are made of conductive materials, such as copper, silicide, aluminum alloy, or the like.

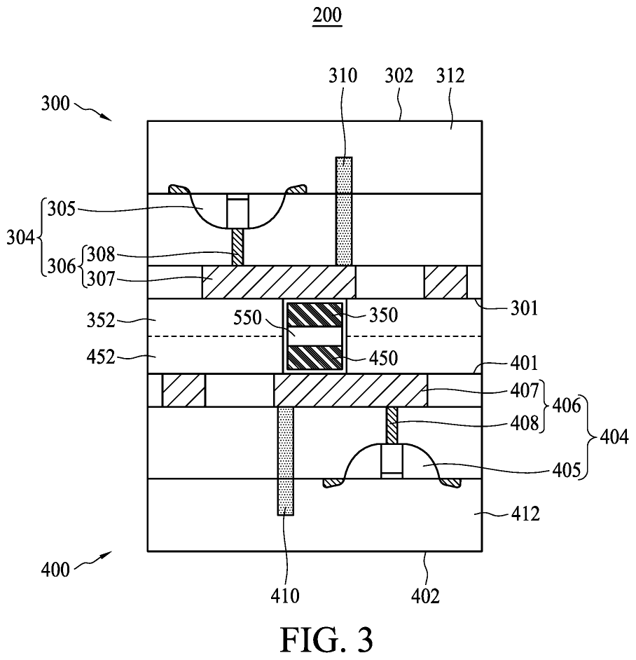

In operation 106, as shown in FIG. 3, the first bonding conductor 350 is bonded to the second bonding conductor 450. A third bonding conductor 550 is formed between the first bonding conductor 350 and the second bonding conductor 450. The third bonding conductor 550 is in contact with the first bonding conductor 350 and the second bonding conductor 450. In some embodiments, before bonding the first bonding conductor 350 and the second bonding conductor 450, the first bonding conductor 350 and the second bonding is conductor 450 are aligned.

In some embodiments, the first bonding conductor 350 is different from the second bonding conductor 450. The third bonding conductor 550 includes a silicide material formed from the first bonding conductor 350 and the second bonding conductor 450 through a thermal treating process or an electrical treating process.

In some embodiments, the silicide material can be tungsten silicide, cobalt silicide, titanium silicide, nickel silicide, molybdenum silicide, or a combination thereof. In some embodiments, one of the first bonding conductor 350 and the second bonding conductor 450 includes a silicon material, and another of the first and second bonding conductors includes a metal material, such as tungsten, cobalt, titanium, nickel, molybdenum or the like. In some embodiments, the first bonding conductor 350 and the second bonding conductor 450 may include different silicide materials.

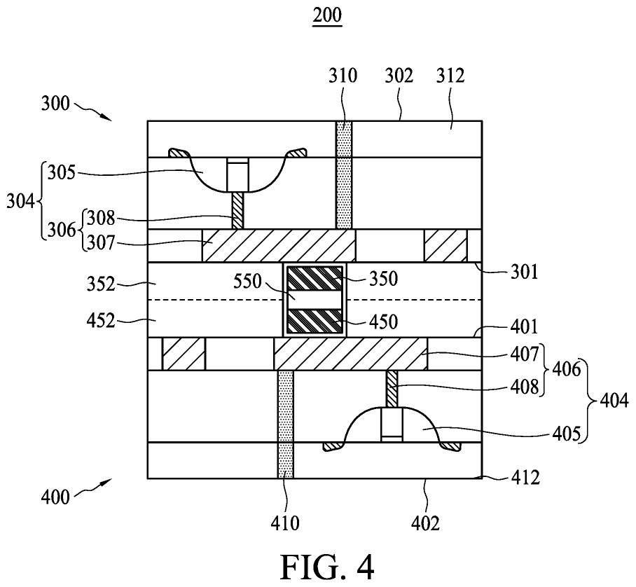

In operation 108, as shown in FIG. 4, a portion of the first semiconductor layer 300 is removed from the first bottom surface 302 of the first semiconductor layer 300, and the first TSV 310 is exposed.

In some embodiments, a portion of the second semiconductor layer 400 is removed from the second bottom surface 402 of the second semiconductor layer 400, and the second TSV 410 is exposed.

In some embodiments, the operation 108 may include a suitable removing process, such as a grinding process, a polishing operation (for example, chemical mechanical polishing), an etching process or the like.

In some embodiments, the first TSV 310 may further electrically connect to another redistribution layer disposed over the is first bottom surface 302. In some embodiments, the second TSV 410 may further electrically connect to another metal pad or solder ball of a circuit board disposed over the second bottom surface 402.

As shown in FIG. 4, the semiconductor structure 200 is provided. The semiconductor structure 200 includes the first semiconductor layer 300, the second semiconductor layer 400, the first bonding conductor 350, the second bonding conductor 450 and the third bonding conductor 550. The first semiconductor layer 300 includes the first top surface 301 and the first electronic circuit structure 304. The second semiconductor layer 400 is disposed over the first semiconductor layer 300. The second semiconductor layer 400 includes the second top surface 401 and the second electronic circuit structure 404. The first bonding conductor 350 is disposed over the first top surface 301. The first bonding conductor 350 is coupled to the first electronic circuit structure 304. The second bonding conductor 450 is disposed over the second top surface 401. The second bonding conductor 450 is coupled to the second electronic circuit structure 404. The third bonding conductor 550 is disposed between the first bonding conductor 350 and the second bonding conductor 450. The third bonding conductor 550 is in contact with the first bonding conductor 350 and the second bonding conductor 450. The first bonding conductor 350 is different from the second bonding conductor 450. The third bonding conductor 550 includes a silicide material. The first TSV 310 is disposed in the first semiconductor layer 300. The first TSV 310 is in contact with the first electronic circuit structure 304. The first TSV 310 extends from the first electronic circuit structure 304 toward the first bottom surface 302. The second TSV 410 is disposed in the second semiconductor layer 400. The second TSV 410 is in contact with the second electronic circuit structure 404. The second TSV 410 extends from the second electronic circuit structure 404 toward the second bottom surface 402. One of the first bonding conductor 350 and the second bonding conductor 450 includes a silicon material, and another of the first and second bonding conductors includes a metal material. The first electronic circuit structure 304 includes the first electronic component 305 and the first interconnection circuit 306 coupled to the first electronic component 305. The second electronic circuit structure 404 includes the second electronic component 405 and the second interconnection circuit 406 coupled to the second electronic component 405. The first electronic component 305 is the first transistor formed on the first substrate 312. The second electronic component 405 includes the second transistor formed on the second substrate 412. The first TSV 310 is in contact with the first interconnection circuit 306. The first TSV 310 extends from the first interconnection circuit 306 toward the first bottom surface 302. The first interconnection circuit 306 includes the first conductive pad 307 and the first conductive plug 308 in contact with the first conductive pad 307. The first TSV 310 extends from the first conductive pad 307 toward the first bottom surface 302. The first conductive plug 308 is in contact with the first electronic component 305. The second interconnection circuit 406 includes the second conductive pad 407 and the second conductive plug 408 in contact with the second conductive pad 407. The second conductive plug 408 is in contact with the second electronic component 405. The first dielectric material 352 is disposed over the first top surface 301. The first bonding conductor 350 is embedded in the first dielectric material 352. The second dielectric material 452 is disposed over the second top surface 401. The second bonding conductor 450 is embedded in the second dielectric material 452.

In conclusion, with the configuration of the semiconductor structure of the present disclosure, the bonding conductor may include at least a silicide material. This design can effectively decrease the contact resistance between two semiconductor layers and thus consume less power. In addition, the silicide material has better thermal stability.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

One aspect of the present disclosure provides a method for manufacturing a semiconductor structure. The method comprises forming a first bonding conductor over a first top surface of a first semiconductor layer, wherein the first bonding conductor is coupled to a first electronic circuit structure formed in the first semiconductor layer; forming a second bonding conductor over a second top surface of a second semiconductor layer, wherein the second bonding conductor is coupled to a second electronic circuit structure formed in the second semiconductor layer; and bonding the first bonding conductor and the second bonding conductor, wherein a third bonding conductor is formed between the first bonding conductor and the second bonding conductor, and the third bonding conductor is in contact with the first bonding conductor and the second bonding conductor, wherein the first bonding conductor is different from the second bonding conductor, and the third bonding conductor includes a silicide material formed from the first bonding conductor and the second bonding conductor.

Another aspect of the present disclosure provides a semiconductor structure. The semiconductor structure comprises a first semiconductor layer including a first top surface and a first electronic circuit structure; a second semiconductor layer disposed over the first semiconductor layer, wherein the second semiconductor layer includes a second top surface and a second electronic circuit structure; a first bonding conductor disposed over the first top surface, wherein the first bonding conductor is coupled to the first electronic circuit structure; a second bonding conductor disposed over the second top surface, wherein the second bonding conductor is coupled to the second electronic circuit structure; a third bonding conductor disposed between the first bonding conductor and the second bonding conductor, wherein the third bonding conductor is in contact with the first bonding conductor and the second bonding conductor, wherein the first bonding conductor is different from the second bonding conductor, and the third bonding conductor includes a silicide material.

The scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that is perform substantially the same function or achieve substantially the same result as the corresponding embodiments described herein may be utilized according to the present disclosure. Accordingly, the appended claims are intended to include within their scope such processes, machines, manufacture, compositions of matter, means, methods and steps.

What is claimed is:

1. A method for manufacturing a semiconductor structure, comprising:
forming a first bonding conductor over a first top surface of a first semiconductor layer, wherein the first bonding conductor is coupled to a first electronic circuit structure formed in the first semiconductor layer;
forming a second bonding conductor over a second top surface of a second semiconductor layer, wherein the second bonding conductor is coupled to a second electronic circuit structure formed in the second semiconductor layer; and
bonding the first bonding conductor and the second bonding conductor, wherein a third bonding conductor is formed between the first bonding conductor and the second bonding conductor, and the third bonding conductor is in contact with the first bonding conductor and the second bonding conductor.

2. The method of claim 1, further comprising:
forming a first through semiconductor via (TSV) in the first semiconductor layer, wherein the first TSV is coupled to the first bonding conductor.

3. The method of claim 2, further comprising:
forming a second TSV in the second semiconductor layer, wherein the second TSV is coupled to the second bonding conductor.

4. The method of claim 2, further comprising:
removing a portion of the first semiconductor layer from a first bottom surface of the first semiconductor layer, wherein the first TSV is exposed.

5. The method of claim 1, wherein the first electronic circuit structure includes a first electronic component and a first interconnection circuit coupled to the first electronic component, and the second electronic circuit structure includes a second electronic component and a second interconnection circuit coupled to the second electronic component.

6. The method of claim 5, wherein the first electronic component is a first transistor formed on a first substrate of the first semiconductor layer, and the second electronic component includes a second transistor formed on a second substrate of the second semiconductor layer.

7. The method of claim 5, further comprising:
forming a first TSV in contact with the first interconnection circuit, wherein the first TSV extends from the first interconnection circuit toward a first bottom surface of the first semiconductor layer.

8. The method of claim 7, further comprising:
forming a first conductive pad and a first conductive plug of the first interconnection circuit, wherein the first TSV extends from the first conductive pad toward the first bottom surface, and the first conductive plug is in contact with the first electronic component and the first conductive pad.

9. The method of claim 1, wherein the first bonding conductor is different from the second bonding conductor, the third bonding conductor includes a silicide material formed from the first bonding conductor and the second bonding conductor, one of the first bonding conductor and the second bonding conductor includes a silicon material, another of the first and second bonding conductors includes a metal material, and the third bonding conductor is formed through a thermal treating process or an electrical treating process.

10. The method of claim 1, further comprising:
forming a first dielectric material over the first top surface, wherein the first bonding conductor is embedded in the first dielectric material; and
forming a second dielectric material over the second top surface, wherein the second bonding conductor is embedded in the second dielectric material.

11. A semiconductor structure, comprising:
a first semiconductor layer including a first top surface and a first electronic circuit structure;
a second semiconductor layer disposed over the first semiconductor layer, wherein the second semiconductor layer includes a second top surface and a second electronic circuit structure;
a first bonding conductor disposed over the first top surface, wherein the first bonding conductor is coupled to the first electronic circuit structure;
a second bonding conductor disposed over the second top surface, wherein the second bonding conductor is coupled to the second electronic circuit structure; and
a third bonding conductor disposed between the first bonding conductor and the second bonding conductor, wherein the third bonding conductor is in contact with the first bonding conductor and the second bonding conductor.

12. The semiconductor structure of claim 11, further comprising:
a first through semiconductor via (TSV) disposed in the first semiconductor layer, wherein the first TSV is in contact with the first electronic circuit structure, and the first TSV extends from the first electronic circuit structure toward a first bottom surface of the first semiconductor layer.

13. The semiconductor structure of claim 12, further comprising:
a second through semiconductor via (TSV) disposed in the second semiconductor layer, wherein the second TSV is in contact with the second electronic circuit structure, and the second TSV extends from the second electronic circuit structure toward a second bottom surface of the second semiconductor layer.

14. The semiconductor structure of claim 11, wherein the first bonding conductor is different from the second bonding conductor, and the third bonding conductor includes a silicide material, one of the first bonding conductor and the second bonding conductor includes a silicon material, and another of the first and second bonding conductors includes a metal material.

15. The semiconductor structure of claim 1, wherein the first electronic circuit structure includes a first electronic component and a first interconnection circuit coupled to the first electronic component, and the second electronic circuit structure includes a second electronic component and a second interconnection circuit coupled to the second electronic component.

16. The semiconductor structure of claim 15, wherein the first electronic component is a first transistor formed on a first substrate of the first semiconductor layer, and the second electronic component includes a second transistor formed on a second substrate of the second semiconductor layer.

17. The semiconductor structure of claim 15, further comprising:
a first TSV in contact with the first interconnection circuit, wherein the first TSV extends from the first interconnection circuit toward a first bottom surface of the first semiconductor layer.

18. The semiconductor structure of claim 17, wherein the first interconnection circuit includes a first conductive pad and a first conductive plug in contact with the first conductive pad, wherein the first TSV extends from the first conductive pad toward the first bottom surface, and the first conductive plug is in contact with the first electronic component.

19. The semiconductor structure of claim 15, wherein the second interconnection circuit includes a second conductive pad and a second conductive plug in contact with the second conductive pad, wherein the second conductive plug is in contact with the second electronic component.

20. The semiconductor structure of claim 11, further comprising:
a first dielectric material disposed over the first top surface, wherein the first bonding conductor is embedded in the first dielectric material; and
a second dielectric material disposed over the second top surface, wherein the second bonding conductor is embedded in the second dielectric material.
